(19) United States
(12) Patent Application Publication
(10) Pub. No.: US 2017/0288040 A1
(43) Pub. Date: Oct. 5, 2017

(54) METHOD OF FORMING SIGE CHANNEL FORMATION REGION

(71) Applicants: Commissariat à l'Énergie Atomique et aux Énergies Alternatives, Paris (FR); STMicroelectronics, Inc., Coppell, TX (US); International Business Machines Corporation, Armonk, NY (US)

(72) Inventors: Emmanuel Augendre, Montbonnot (FR); Qing Liu, Guilderland, NY (US); Rajasekhar Venigalla, Hopewell Jct., NY (US)

(73) Assignees: Commissariat à l'Énergie Atomique et aux Énergies Alternatives, Paris (FR); STMicroelectronics, Inc., Coppell, TX (US); International Business Machines Corporation, Armonk, NY (US)

(21) Appl. No.: 15/088,960

(22) Filed: Apr. 1, 2016

(51) Int. Cl. H01L 29/66; H01L 21/3065; H01L 21/225; H01L 27/12; H01L 29/78; H01L 21/02

(52) U.S. Cl. CPC H01L 29/66795; H01L 29/785; H01L 21/02532; H01L 21/2257; H01L 27/1211; H01L 21/02164; H01L 21/3065

(57) ABSTRACT

A method comprising: forming an SiGe layer on sidewalls of one or more fins of a semiconductor device by a non-selective deposition of amorphous SiGe, the fins being formed of Si or SiGe; depositing a silicon oxide layer over the SiGe layer; and forming an SiGe channel formation region within each fin by performing Ge enrichment to diffuse Ge atoms from the SiGe layer into the one or more fins.

### FIELD

The present disclosure relates to the field of transistors devices, and in particular to a method of forming a field effect transistor having a silicon germanium channel formation region.

### BACKGROUND

A finFET (fin-Field Effect Transistor) architecture has been proposed in which, rather than having planar channels, transistors are formed having 3-dimensional channels in the form of semiconductor fins. It has also been proposed to fabricate finFETs over an SOI (silicon on insulator) substrate. Such an architecture has the advantage of allowing a relatively simple fabrication sequence.

Furthermore, in order to improve performance, SiGe alloys are being investigated as a potential channel material. Such SiGe alloys for example comprise a composition of Si1-xGex, with x varying up to 1.

In order to enhance the mobility of n- and p-type charge carriers and to provide threshold voltage adjustment, it would also be desirable to co-integrate in a same integrated circuit finFETs having channel materials with varying Ge content, and having varying strain levels.

One approach for forming SiGe fins would be to use epitaxial growth in a vertical direction, the duration of the growth period defining the fin height. However, there is a difficulty in using such a technique to form p-type channel devices having a channel region under compressive strain. Indeed, there is a limiting thickness, known in the field as the critical thickness, above which plastic relaxation of a strained SiGe film occurs, leading to strain loss through defect formation. For example, for an SiGe film containing 50% Ge and being grown on silicon, the critical thickness is around 10 nm.

There is thus a need in the art for a method of forming a SiGe channel region of relatively large height, and which for example permits a co-integration of varying strain levels and/or varying levels of Ge content.

### SUMMARY

It is an aim of embodiments of the present disclosure to at least partially address one or more needs in the prior art.

According to one embodiment, there is provided a method comprising: forming an SiGe layer on sidewalls of one or more fins of a semiconductor device by a non-selective deposition of amorphous SiGe, the fins being formed of Si or SiGe; depositing a silicon oxide layer over the SiGe layer; and forming an SiGe channel formation region within each fin by performing Ge enrichment to diffuse Ge atoms from the SiGe layer into the one or more fins.

According to one embodiment, the fins are formed on a substrate, and during the formation of the SiGe layer a top surface of each fin is covered by a hard mask layer.

According to one embodiment, the SiGe layer is crystallized following deposition by an annealing step.

According to one embodiment, the annealing step is performed at a temperature in the range of 500° C. to 600° C.

According to one embodiment, the Ge enrichment comprises one or more oxidation and diffusion cycles.

According to one embodiment, the one or more oxidation and diffusion cycles are performed at a temperature in the range of 900° C. to 1050° C.

According to one embodiment, the duration of the one or more oxidation cycles is such that the SiGe layer is consumed.

According to one embodiment, the SiGe layer is formed on the side walls of a plurality of fins formed in parallel with each other, the thickness of the SiGe layer being less than half of the spacing between adjacent fins.

According to one embodiment, the spacing between adjacent fins once covered by the SiGe layer is at least 5 nm.

According to one embodiment, the method further comprises, before forming the SiGe layer, masking one or more further fins of the semiconductor device.

According to one embodiment, the SiGe layer has a thickness of between 5 and 15 nm.

According to one embodiment, the one or more fins have a height of at least 20 nm. According to one embodiment, the Ge enrichment increases the Ge content in the fins to a level of between 20 and 95 percent.

According to one embodiment, the silicon oxide layer covers the hardmask layer, and the method further comprises, after performing the Ge enrichment, recessing the silicon oxide layer by etching to expose the hardmask layer of each fin stack.

According to one embodiment, the method further comprises removing the hardmask layer of each fin stack by etching.

According to one embodiment, the method further comprises removing the silicon oxide layer using selective isotropic reactive-ion etching.

According to one embodiment, the method further comprises forming one or more fin field effect transistors (finFETs) each having a channel formation region in one of the one or more fins.

According to one embodiment, the one or more fins extend from a substrate formed of an insulating layer.

According to a further aspect, there is provided a method comprising providing one or more fins on a substrate, the fins being formed of Si or SiGe; exposing sidewalls of each fin down to the substrate; forming an SiGe layer on the exposed sidewalls of the one or more fins; depositing a silicon oxide layer over the SiGe layer; and forming an SiGe channel formation region within each fin by performing Ge enrichment to diffuse Ge atoms from the SiGe layer into the one or more fins.

According to yet a further aspect, there is provided a method comprising: providing one or more fins on a substrate, the fins being formed of Si or SiGe, a top surface of each fin being covered by a hardmask layer; forming an SiGe layer on exposed sidewalls of the one or more fins; depositing a silicon oxide layer over the SiGe layer; and forming an SiGe channel formation region within each fin by performing Ge enrichment to diffuse Ge atoms from the SiGe layer into the one or more fins.

### BRIEF DESCRIPTION OF THE DRAWINGS

The foregoing and other features and advantages will become apparent from the following detailed description of embodiments, given by way of illustration and not limitation with reference to the accompanying drawings, in which:

FIGS. 1A to 1I are cross-section views of a portion of a semiconductor device at various steps during the fabrication of an SiGe channel formation region according to an example embodiment;

FIG. 2 is a cross-section view of a semiconductor structure representing an alternative method step to the one of FIG. 1B according to an example embodiment of the present disclosure;

FIG. 3 is a perspective view of a portion of a semiconductor structure comprising finFETs according to an example embodiment of the present disclosure; and

FIG. 4 is a flow diagram illustrating steps in a method of forming an SiGe channel formation region according to an example embodiment.

As usual when representing semiconductor structures, the various figures are not drawn to scale.

### DETAILED DESCRIPTION

The embodiments described herein relate to the formation of an SiGe channel formation region in a particular type of finFET. It will however be apparent to those skilled in the art that the techniques described herein could be applied to other types of FET devices in which an SiGe channel formation region is to be formed in a semiconductor fin.

The term “channel formation region” is used herein to designate the semiconductor region of a device in which a channel will be formed when the device is operational.

The term “fin” is used to designate any 3-dimensional form extending from a substrate and within which a channel formation region is or will be formed.

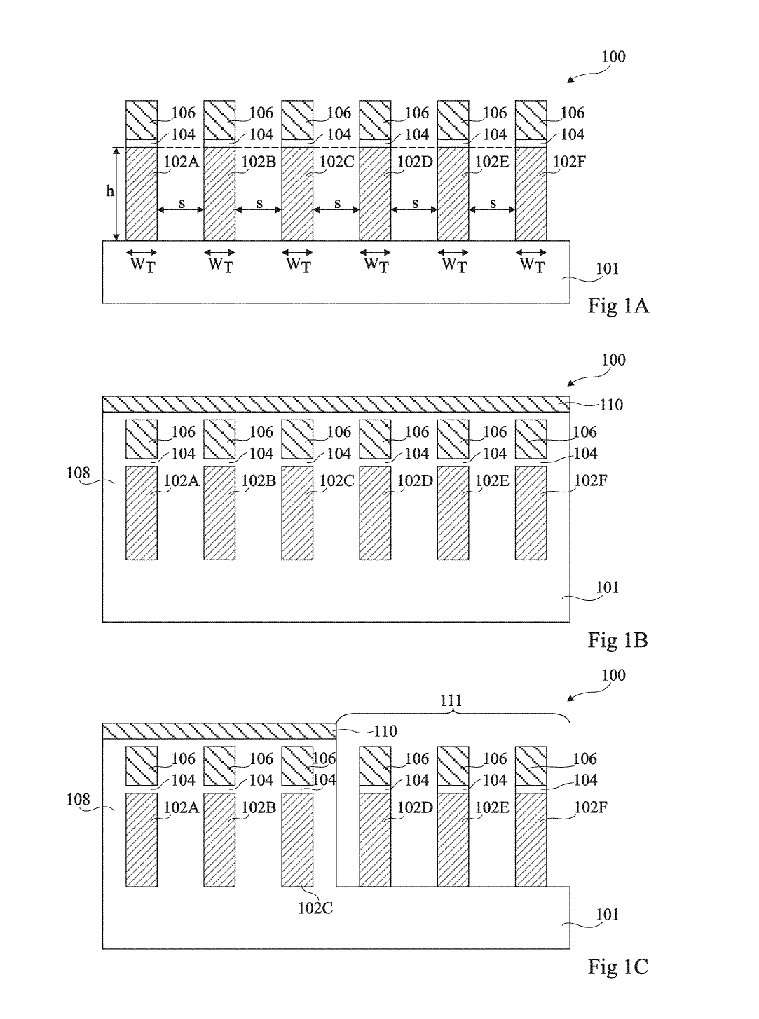

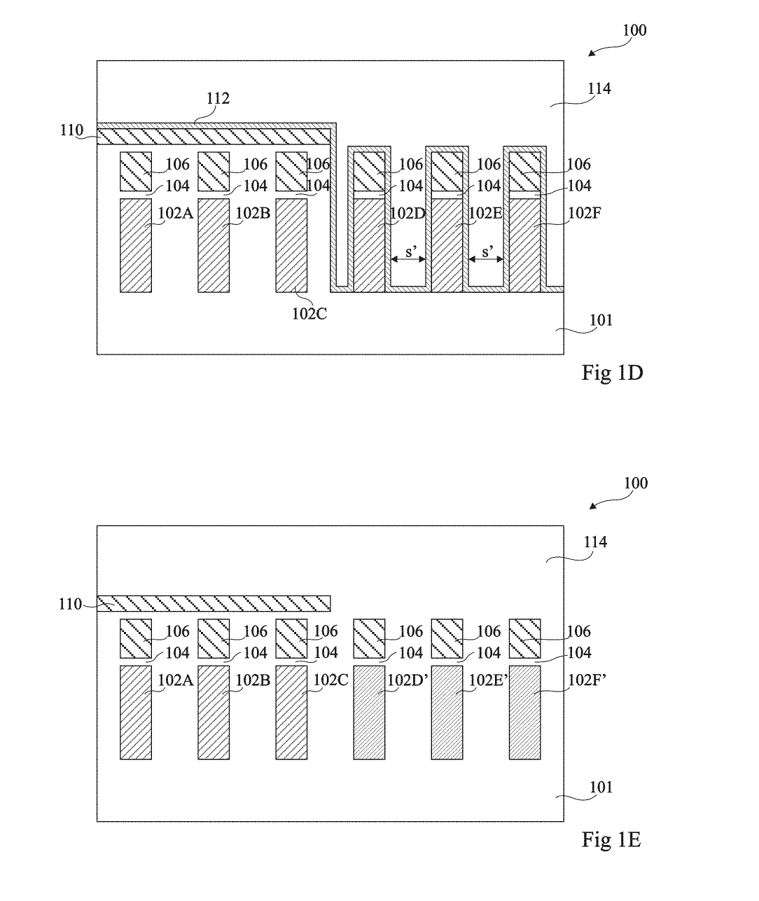

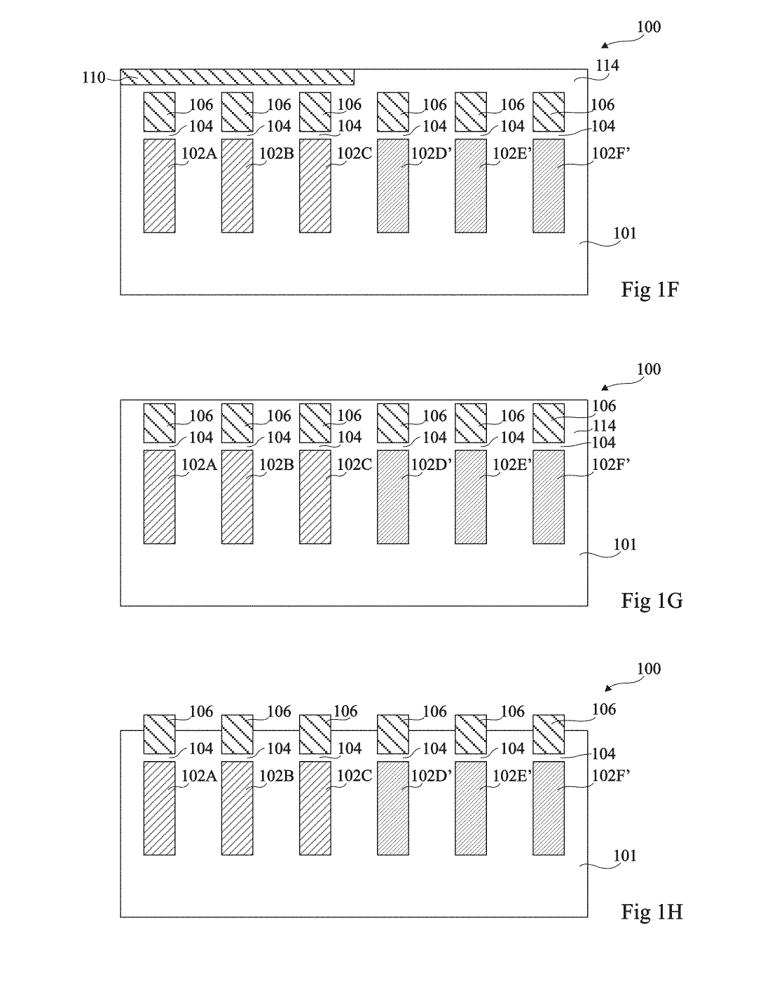

The term “around” is used to indicate a tolerance of +/−10% of the value in question. FIGS. 1A to 1I are cross-section views of a portion 100 of a semiconductor device part way through fabrication and represent a method of forming SiGe channel formation regions of finFET transistors.

FIG. 1A illustrates the semiconductor device having a substrate 101 formed of an insulator, such as silicon oxide, with a thickness of between 10 and 400 nm. Semiconductor fins 102A to 102F are formed on the surface of the substrate 101. For example, the fins 102A to 102F are formed of silicon, or of SiGe with a Ge content of for example between 0 and 80 percent. One, some or all of the fins 102A to 102F may be strained. For example, one or more of the fins may be formed of Si and be strained in tension, and/or one or more of the fins may be formed of SiGe and strained in compression. FIG. 1A illustrates only a relatively small portion of the semiconductor device in which there are six fins, and of course in practise the method can be applied to a portion of the semiconductor device having any number of fins. The cross-section shown in FIGS. 1A to 1I passes through a channel formation region of each fin, which for example corresponds to only a portion of the length of each fin. Each fin for example has a width WT in the range 5 to 20 nm, and a height h in the range 20 to 60 nm. Terms such as “width”, “height”, “top”, “bottom” and “side”, which depend on the orientation the device, will be assumed herein to apply when the device is orientated as shown in the figures.

Adjacent fins are for example separated from each other by a spacing s of between 20 and 40 nm. For example, fins have been formed by a SIT (Sidewall Image Transfer) process, and/or a SADP (self-aligned double patterning) process. As represented in FIG. 1A, the formation process of the fins 102A to 102F for example results in each fin being part of a stack, each fin stack comprising a layer 104 of silicon oxide formed over the fin, for example of 2 to 4 nm in thickness, and a hardmask layer 106, for example of silicon nitride, with a thickness of 20 to 40 nm, formed over the oxide layer 104. These layers 104, 106 form a hardmask layer, and such a layer is for example maintained above each fin to aid a uniform Ge enrichment throughout the complete fin height, as will be described in more detail below.

FIG. 1B illustrates the structure after a step in which a layer 108 of silicon oxide is deposited, filling the spaces between the fins 102A to 102F, and rising to a level covering the tops of each of the fin stacks, including the hardmask layers 106, for example by between 5 and 10 nm. For example, a thicker oxide layer is initially deposited, and then CMP (chemical mechanical polishing) is used to bring the surface of the oxide layer 108 down to the level covering the fin stacks. Alternatively, the CMP is used to bring the surface of the oxide down to the level of the surface of the hardmask layers 106, and then another silicon oxide deposition is for example performed to cover the hardmask layers 106, for example by between 5 and 10 nm. A hardmask 110, for example formed of a layer of nitride, is then formed over the oxide layer 108. The hardmask 110 for example has a thickness of between 6 and 10 nm.

FIG. 1C illustrates the structure after a step in which the top of the hardmask 110 is patterned using a photolithographic step and RIE (reactive ion etching), such that a region 111 of the hardmask 110 and of the oxide layer 108 is removed by etching. This for example results in the side walls of the fins 102D to 102F being exposed down to the substrate 101. The etching process for example involves first etching the hardmask 110 in the region 111, and then selectively etching the oxide layer 108 with respect to the hardmask layers 106 using an RIE etch, such that the oxide layer 108 is removed in the region 111 and the hardmask layers 106 remain covering the fin stacks of fins 102D to 102F.

FIG. 1D illustrates the structure after a step in which a layer 112 of SiGe is for example deposited over the structure, covering the walls of the fin stacks in the region 111, and in particular covering the sidewalls of the exposed fins 102D to 102F. For example, the SiGe layer 112 is of amorphous SiGe formed by non-selective deposition. The thickness and Ge percentage of this layer 112 are for example chosen to provide a desired amount of Ge for diffusion into the fins 102D to 102F, as will be described in more detail below. For example, the SiGe layer 112 has a thickness of between 5 and 15 nm. The thickness of the SiGe layer is also for example chosen such that there remains a spacing s′ between the SiGe layer 112 on adjacent fins of at least 5 nm, leaving a large enough opening for oxide to be deposited in the spacing s′. After deposition, the SiGe layer 112 is for example transformed into a crystalline layer in the regions in which it is in contact with the fins 102D to 102F, for example by an annealing step at a temperature in the range of 500 to 600° C., and for example a temperature of 550° C., for around 2 minutes in a neutral atmosphere. By transforming the SiGe layer 112 into a crystalline layer at a low growth crystallization rate at a relatively low temperature of less than 600° C., there will be a low formation of SiGe grain boundaries, which will favour uniform SiGe oxidation during a subsequent Ge enrichment process described in more detail below.

The thickness of the SiGe layer 112 is for example lower than the critical thickness defined based on the Ge content of the SiGe layer 112 and the composition of the fins on which the SiGe layer 112 is formed.

A silicon oxide layer 114 is then for example deposited over the structure, filling the spaces between the SiGe layer 112 covering the fins 102D to 102F, and covering the hardmask layers 106 by around 1 fin height.

FIG. 1E illustrates the structure after a step in which a Ge enrichment process, also known as a condensation process, is performed. Such a Ge enrichment process is for example described in more detail in the publication by T. Tezuka et al. entitled “A Novel Fabrication Technique of Ultrathin and Relaxed SiGe Buffer Layers with High Ge Fraction for Sub-100 nm Strained Silicon-on-Insulator MOSFETs”, Jpn. J. Appl. Phys. Vol. 40 (2001) pp. 2866-2874, part 1, No. 4B, the contents of which is hereby incorporated by reference to the maximum extent permitted by the law.

For example, such Ge enrichments involves an alternation of oxidation and diffusion cycles. The temperature during the oxidation and diffusion is for example chosen to remain below the melting temperature of SiGe at its highest Ge concentration in the device. For example, the oxidation and diffusion are each performed at temperatures in the range 900 to 1050° C. Oxidation involves an atmosphere with a supply of oxygen, whereas diffusion is for example performed in a neutral atmosphere. The total oxidation time is for example chosen such that the entire SiGe layer 112 is consumed. The total diffusion time is for example chosen such that the Ge content in the fins 102D to 102F reaches a uniform level. As a typical example, the diffusion time is for example in the range of 5 to 10 minutes for an oxidation performed at 900° C. and diffusion performed at 1000° C.

The oxidation step of the Ge enrichment process results in a reaction between the silicon atoms in the SiGe layer 112 with the oxide 114 creating SiO2, the consumed atoms of oxygen being replaced by the oxygen supply in the atmosphere. This frees atoms of Ge from the SiGe layer 112. These Ge atoms are then diffused to the fins 102D to 102F during the diffusion cycles, increasing the Ge content of the fins. Thus as represented in FIG. 1E, by the end of the Ge enrichment process, the SiGe layer 112 is consumed, and the fins 102D to 102F become fins 102D′ to 102F having increased Ge content. Thanks to the hardmask layers 106, the tops of the fins 102D to 102F do not contact the SiGe layer 112, leading to a uniform Ge enrichment over the whole height of the fins. The Ge content of the fins 102D′ to 102F′ will depend on their initial Ge content, if any, on the amount of Ge present in the SiGe layer 112, and on the width of the fins. For example, with this process it is possible to increase the Ge content of the fins 102D′ to 102F′ to between 20 to 95 percent.

FIGS. 1F to 1I illustrates steps that may be used, following the Ge enrichment process, to expose the fins 102A to 102F prior to subsequent steps in the finFET formation process.

FIG. 1F illustrates a step in which a CMP (Chemical Mechanical Polishing) operation is used to reduce the height of the silicon oxide layer 114 down to the level of the surface of the hardmask 110.

FIG. 1G illustrates a step in which the hardmask 110 is removed, for example using an HF+EG etch, having the same etch rate for oxide and nitride. The etching is for example performed down to a level within the oxide layer 114.

FIG. 1H illustrates a step in which HF oxide etching is performed to recess the oxide layer 114 and expose the hardmask layers 106 of each of the fin stacks of fins 102A to 102C and 102D′ to 102F′.

FIG. 1I illustrates a step in which the nitride layers 106 are for example etched using a hot phosphoric acid, and the oxide is for example removed using selective isotropic RIE (reactive-ion etching). This for example leaves the substrates 101 having formed thereon the fins 102A to 102C having their original Si or SiGe composition, and the fins 102D′ to 102F′ of SiGe having increased levels of Ge with respect to their original Si or SiGe composition.

The fins 102A to 102C and the fins 102D to 102F are then for example used to form finFET devices, for example by forming one or more wrap-around gates over the fins, as known to those skilled in the art.

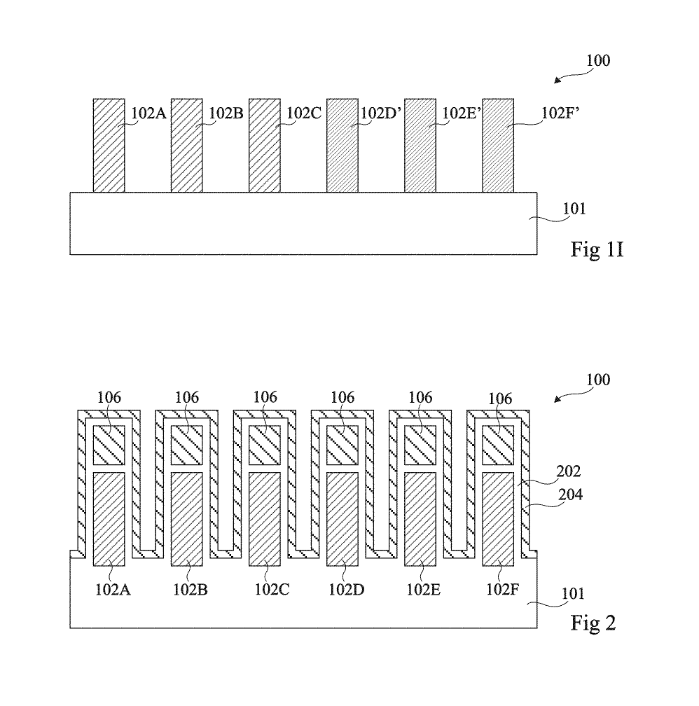

FIG. 2 is cross-section view illustrating a step that may be performed following the step of FIG. 1A, as an alternative to the step shown in FIG. 1B described above. In particular, in some embodiments, rather than filling the spaces s between the fins 102A to 102F with oxide, as shown in FIG. 2, a layer 202 of silicon oxide is deposited over the device, this layer for example having a thickness of between 3 and 6 nm, and a hardmask layer 204, for example of silicon nitride, is then deposited over the oxide layer, the layer 204 for example having a thickness of between 10 and 20 nm. The remaining steps of FIGS. 1C to 1I described above are for example then performed on the structure of FIG. 2.

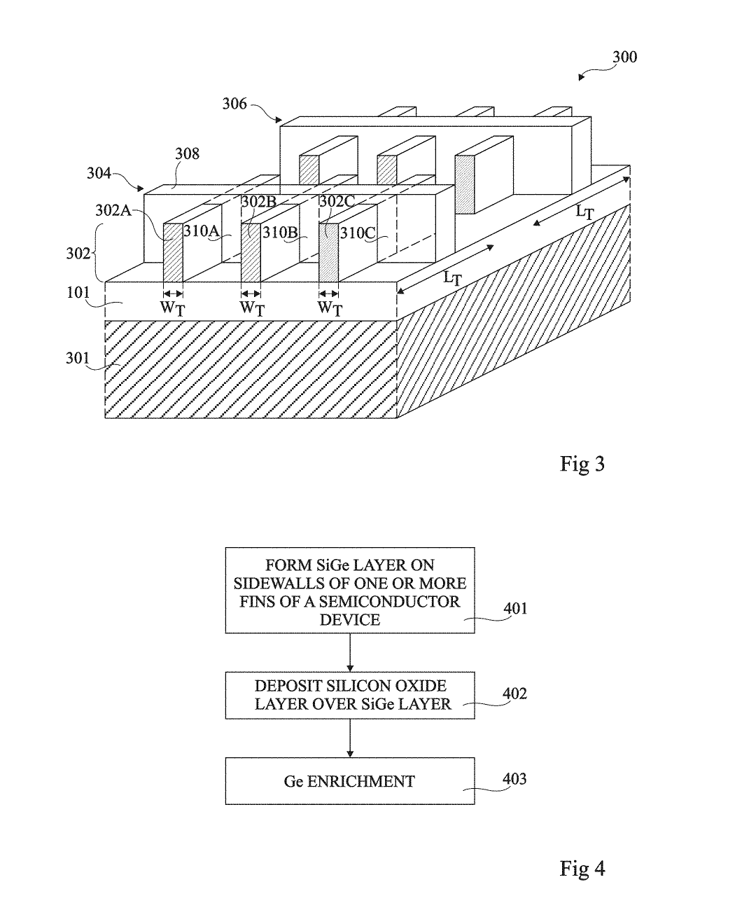

FIG. 3 is a perspective view of a portion 300 of a semiconductor structure comprising finFETs having fins fabricated according to the method of FIGS. 1A to 1I and/or 2.

As illustrated, the semiconductor structure 300 comprises a substrate 301, for example formed of bulk silicon, over which is formed the substrate 101 formed of an insulating layer such as silicon oxide. A semiconductor layer 302 is formed over and in contact with the insulating layer 101, and comprises semiconductor fins 302A, 302B and 302C defining a transistor devices 304. FIG. 3 also illustrates further fins defining further transistor devices 306. The fins 302A, 302B and 302C each have a p-type or n-type channel, and are controlled by a common gate 308. The gate is formed substantially perpendicular to the fins 302A, 302B and 302C. Regions 310A to 310C of the respective fins 302A, 302B and 302C under the gate 308, which are represented by dashed lines in FIG. 3, correspond to the channel formation regions of each fin in which a channel is formed by the application of a voltage to the common gate 308.

The width WT of each transistor in the structure of FIG. 3 corresponds for example to the width of each fin, and the length LT of each transistor for example corresponds to the length of each fin. As illustrated, the fin 302C for example has increased Ge content with respect to the fins 302A and 302B. The Ge enrichment is for example performed over the entire length of the fin, rather than being limited to the channel formation region 310C, although in alternative embodiments the region 111, in which the walls of the fins are exposed to the deposited SiGe layer, may only comprises the channel formation regions of the fins.

FIG. 4 is a flow diagram illustrating steps in a method of forming an SiGe channel formation region according to an example embodiment. It is assumed that a semiconductor device has been formed having one or more fins of Si or of SiGe.

In a step 401, an SiGe layer is formed on the sidewalls of the fins of the semiconductor device, for example by non-selective deposition of amorphous SiGe.

In a step 402, a layer of silicon oxide is deposited over the SiGe layer.

In a step 403, Ge enrichment is performed to form SiGe channel formation regions within each fin, Ge enrichment involving diffusing Ge atoms from the SiGe layer into the one or more fins.

An advantage of the embodiments described herein is that fins are formed with SiGe channel formation regions without depositing an SiGe layer having a thickness exceeding the critical thickness. Furthermore, the method described herein permits uniform Ge content within the SiGe channel formation regions, and permits different fins to have varying Ge content. Yet a further advantage is that the method described herein of increasing the Ge concentration in the fins also yields an increase in the strain, and in particular an increase in compression, of the fins.

An advantage of depositing the non-selective SiGe layer 112 as described in relation to FIG. 1D is that it results in a conformal layer, without facets, and this layer, which covers the whole device, will prevent oxygen from diffusing and possibly oxidizing certain fins during the Ge enrichment process.

Having thus described at least one illustrative embodiment, various alterations, modifications and improvements will readily occur to those skilled in the art.

For example, it will be apparent to those skilled in the art that while the fins in the embodiments described herein are rectangular in cross-section and in plan-view, other forms would be possible.

Furthermore, the particular finFET structure represented in FIG. 3 is merely one example, and it will be apparent to those skilled in the art that many different types of transistors having fins could be formed based on the principles described herein.

The various features described in relation to the various embodiments could be combined, in alternative embodiments, in any combination.

1. A method comprising:
forming an amorphous SiGe layer on sidewalls of one or more fins of a semiconductor device by a non-selective deposition of amorphous SiGe, the fins being formed of Si or SiGe;
crystallizing the amorphous SiGe layer following the non-selective deposition by an annealing step;
depositing a silicon oxide layer over the crystallized SiGe layer; and
forming an SiGe channel formation region within each fin by performing Ge enrichment to diffuse Ge atoms from the crystallized SiGe layer into the one or more fins.

2. The method of claim 1, wherein the fins are formed on a substrate, and during the formation of the amorphous SiGe layer a top surface of each fin is covered by a hard mask layer.

3. (canceled)

4. The method of claim 1, wherein the annealing step is performed at a temperature of 600° C. or less.

5. The method of claim 1, wherein the Ge enrichment comprises one or more oxidation and diffusion cycles.

6. The method of claim 5, wherein the one or more oxidation and diffusion cycles are performed at a temperature in the range of 900° C. to 1050° C.

7. The method of claim 5, wherein the duration of the one or more oxidation cycles is such that the crystallized SiGe layer is consumed.

8. The method of claim 1, wherein the amorphous SiGe layer is formed on the side walls of a plurality of fins formed in parallel with each other, the thickness of the amorphous SiGe layer being less than half of the spacing between adjacent fins.

9. The method of claim 8, wherein the spacing between adjacent fins once covered by the amorphous SiGe layer is at least 5 nm.

10. The method of claim 1, further comprising, before forming the amorphous SiGe layer, masking one or more further fins of the semiconductor device.

11. The method of claim 1, wherein the amorphous SiGe layer has a thickness of between 5 and 15 nm.

12. The method of claim 1, wherein the one or more fins have a height of at least 20 nm.

13. The method of claim 1, wherein the Ge enrichment increases the Ge content in the fins to a level of between 20 and 95 percent.

14. The method of claim 2, wherein the silicon oxide layer covers the hardmask layer, and the method further comprises, after performing the Ge enrichment, recessing the silicon oxide layer by etching to expose the hardmask layer of each fin stack.

15. The method of claim 14, further comprising removing the hardmask layer of each fin stack by etching.

16. The method of claim 15, further comprising removing the silicon oxide layer using selective isotropic reactive-ion etching.

17. The method of claim 1, further comprising forming one or more fin field effect transistors (finFETs) each having the SiGe channel formation region in one of the one or more fins.

18. The method of claim 1, wherein the one or more fins extend from a substrate formed of an insulating layer.

19. A method comprising:
providing one or more fins on a substrate, the fins being formed of Si or SiGe;
exposing sidewalls of each fin down to the substrate;
forming an amorphous SiGe layer on the exposed sidewalls of the one or more fins;
crystallizing the amorphous SiGe layer by an annealing step;
depositing a silicon oxide layer over the crystallized SiGe layer; and
forming an SiGe channel formation region within each fin by performing Ge enrichment to diffuse Ge atoms from the crystallized SiGe layer into the one or more fins.

20. A method comprising:
providing one or more fins on a substrate, the fins being formed of Si or SiGe, a top surface of each fin being covered by a hardmask layer;
forming an amorphous SiGe layer on exposed sidewalls of the one or more fins;
crystallizing the amorphous SiGe layer by an annealing step;
depositing a silicon oxide layer over the crystallized SiGe layer; and
forming an SiGe channel formation region within each fin by performing Ge enrichment to diffuse Ge atoms from the crystallized SiGe layer into the one or more fins.
